(19) United States
(12) Patent Application Publication
(10) Pub. No.: US 2024/0192587 A1
(43) Pub. Date: Jun. 13, 2024

(54) GRIPPING MECHANISM FOR INSPECTION OF RETICLE INNER POD

(71) Applicant: GUDENG EQUIPMENT CO., LTD., New Taipei City (TW)

(72) Inventors: YIN-FENG CHAN, New Taipei City (TW); LIN-HSIN TU, New Taipei City (TW); MING-MO LO, New Taipei City (TW)

(21) Appl. No.: 18/079,899

(22) Filed: Dec. 13, 2022

(51) Int. Cl. G03F 1/66; G03F 1/84

(52) U.S. Cl. CPC G03F 1/66; G03F 1/84

(57) ABSTRACT

A gripping mechanism for inspection of a reticle inner pod includes a quadrilateral frame and fourth gripper units. The four gripper units are respectively disposed at four border strips of the quadrilateral frame and are opposite in pairs. Each gripper unit has a body, a first gripping portion and a second gripper portion. The first and second gripping portions are respectively located on different positions of the body. The first gripping portions form a first gripping plane, and the second gripping portions form a second gripping plane. At least two adjacent gripper units have a power member, which is in power connection with the body so as to adjust a distance between two bodies opposite to each other. The gripping mechanism for the inspection of the reticle inner pod is capable of securely gripping the reticle inner pod during transportation or turning of reticles.

### BACKGROUND OF THE INVENTION

### 1. Field of the Invention

The present invention relates a mechanism for gripping a workpiece, and in particular to a gripping mechanism for inspection of a reticle inner pod.

### 2. Description of the Related Art

In the semiconductor industry, in the seek of smaller critical dimensions (CD) of integrated circuits, a current trend is to adopt extreme ultraviolet lithography (EUV) processes. The EUV processes involve exclusive EUV reticles and protection pods thereof to prevent costly reticles from damage. In increasingly stricter manufacturing requirements, in order to prevent the reticles from contamination of dust particles, optical inspection on reticle pods, and more particularly on EUV reticle inner pods, is necessary.

However, a reticle inner pod itself is also prone to damage. Moreover, the market currently lacks mechanisms capable of securely gripping the reticle inner pod during turning and transportation processes.

### BRIEF SUMMARY OF THE INVENTION

Therefore, in view of the various issues of a conventional reticle inner pod, the present invention provides a gripping mechanism for inspection of a reticle inner pod.

To achieve the above and other objects, the present invention provides a gripping mechanism for inspection of a reticle inner pod. The gripping mechanism includes a quadrilateral frame having four border strips, and four gripper units respectively disposed at the four border strips. The four gripper units are opposite in pairs. Each of the gripper unit has a body, a first gripping portion and a second gripping portion. The first gripping portion and the second gripping portion are respectively located on different positions of the body. The respective first gripping portions of the four gripper units form a first gripping plane, and the respective second gripping portions of the four gripper units form a second gripping plane. At least two adjacent of the gripper units have a power member, which is in power connection with the body and adjusts a distance between the two bodies opposite to each other.

In one embodiment of the present invention, the first gripping portion and the second gripping portion are grooves parallel to the border strips.

In one embodiment of the present invention, the first gripping plane is parallel to the second gripping plane.

In one embodiment of the present invention, the gripper units further include a plurality of adhesive tapes respectively disposed on positions near the first gripping portion and the second gripping portion.

In one embodiment of the present invention, the gripper units further include a packing element, which is connected to the body and packs against the body.

A gripping mechanism for inspection of a reticle inner pod is further provided according to the present invention. The gripping mechanism includes a quadrilateral frame having four border grips, two power units respectively in power connection with at least two adjacent border strips to adjust a distance between the two border strips opposite to each other, and four gripper units respectively disposed at the four border strips. The four gripper units are opposite in pairs. Each of the gripper unit has a body, a first gripping portion and a second gripping portion. The first gripping portion and the second gripping portion are respectively located on different positions of the body. The respective first gripping portions of the four gripper units form a first gripping plane, and the respective second gripping portions of the four gripper units form a second gripping plane.

In one embodiment of the present invention, the first gripping portion and the second gripping portion are grooves parallel to the border strips.

In one embodiment of the present invention, the first gripping plane is parallel to the second gripping plane.

In one embodiment of the present invention, the gripper units further include a plurality of adhesive tapes respectively disposed on positions near the first gripping portion and the second gripping portion.

Thus, the gripping mechanism for the inspection of the reticle inner pod, with different gripping planes formed by the gripper units disposed on four sides, is capable of stably gripping the reticle inner pod and adapting to upper and lower covers in different sizes and shapes. In an inspection process of the reticle inner pod, the reticle is effectively prevented from falling off as well as damage during transportation or turning of the reticle.

### BRIEF DESCRIPTION OF THE DRAWINGS

FIG. 1 is a perspective schematic diagram of a gripping mechanism for inspection of a reticle inner pod according to a first embodiment of the present invention.

FIG. 2A is a schematic diagram of a first gripping plane according to the first embodiment of the present invention.

FIG. 2B is a schematic diagram of a second gripping plane according to the first embodiment of the present invention.

FIG. 3 is a perspective schematic diagram of a quadrilateral frame according to a second embodiment of the present invention.

### DETAILED DESCRIPTION OF THE INVENTION

To fully understand the present invention, specific embodiments are described in detail with the accompanying drawings below. A person skilled in the art would be able to understand the objects, features and effects on the basis of the disclosure of the present application. It should be noted that, the present application can be specifically implemented or applied in other different specific embodiments, and various modifications and variations may also be made to the various details given in the present application on the basis of different perspectives and applications without departing from the spirit of the present invention. Related technical contents of the present invention are further described by way of the embodiments below. However, it should be noted that the disclosure is not to be interpreted as limitations to the scope of the claims of the present invention.

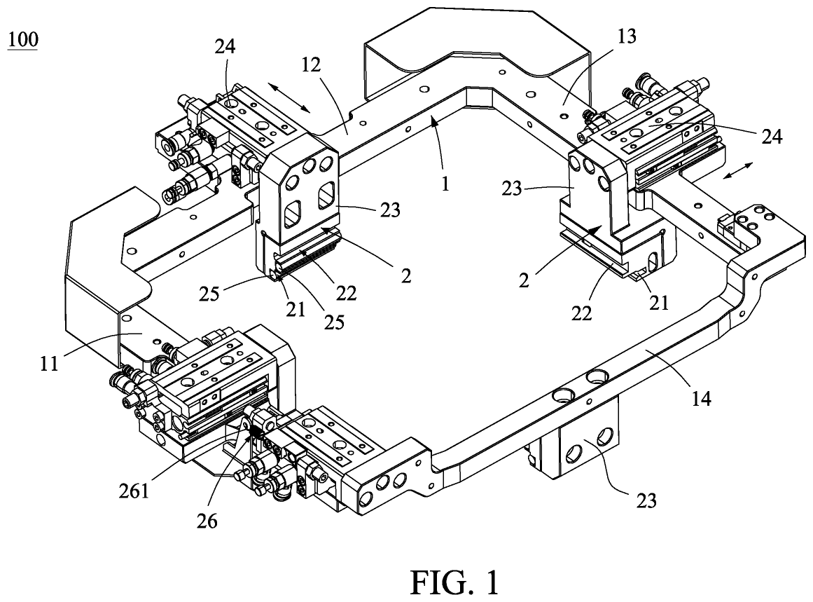

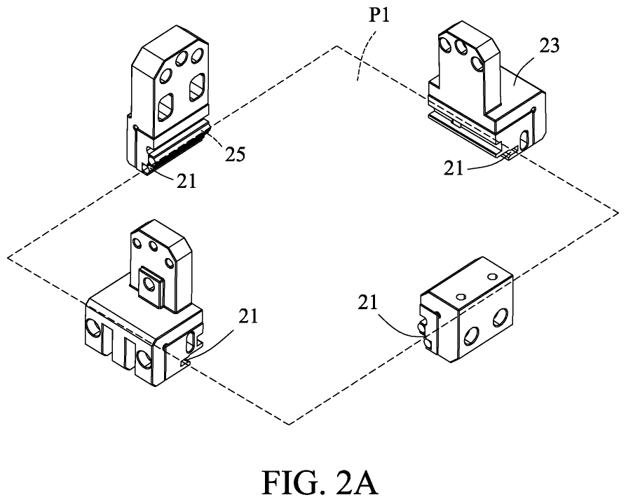

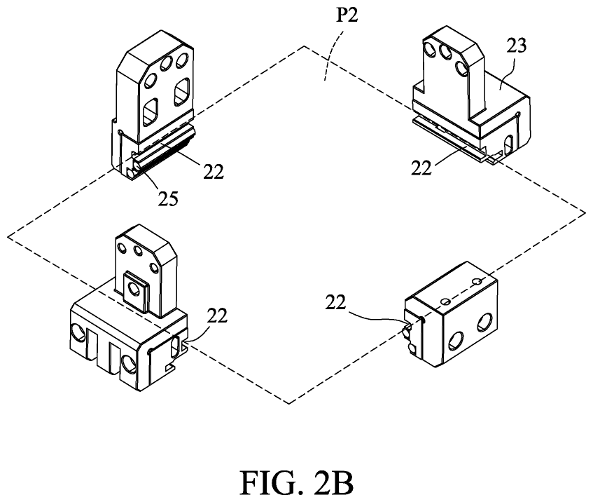

As shown in FIG. 1 to FIG. 2B, a gripping mechanism 100 for inspection of a reticle inner pod according to an embodiment of the present invention includes a quadrilateral frame 1 and four gripper units 2.

The quadrilateral frame 1 has four border strips 11, 12, 13 and 14. The border strips 11 and 13 are opposite to each other, and the border strips 12 and 14 are opposite to each other. The four border strips 11, 12, 13 and 14 may have equal lengths to be in a square form, or may have different lengths to be in a rectangular form.

The four gripper units 2 are respectively disposed at the four border strips 11, 12, 13 and 14, and are opposite in pairs. Each of the gripper unit 2 has a body 23, a first gripping portion 21 and a second gripping portion 22. The first gripping portion 21 and the second gripping portion 22 are respectively located on different positions of the body 23. For example, in this embodiment, the first gripping portion 21 and the second gripping portion 22 are grooves parallel to the border strip, and the first gripping portion 21 and the second gripping portion 22 are arranged in parallel in a top-bottom direction (a normal direction of the quadrilateral frame 1). That is to say, the respective first gripping portions 21 of the four gripper units 2 form a first gripping plane P1 (as shown in FIG. 2A), and the respective second gripping portions 22 of the four gripper units 2 form a second gripping plane P2 (as shown in FIG. 2B). In this embodiment, the second gripping plane P2 is parallel to the first gripping plane P1 and is slightly higher than the first gripping plane P1.

The first gripping plane P1 and the second gripping plane P2 may respectively correspond to reticle pods (not shown) having different sizes and shapes, or upper and lower covers of one single type of reticle pod, wherein which gripping plane corresponding to the upper cover or the lower cover is not specifically defined.

How the gripping mechanism 100 for inspection of a reticle inner pod of the present invention performs gripping of a reticle pod is described below.

As shown in FIG. 1, at least two adjacent gripper units 2 have a power member 24, which is in power connection with the bodies 23 so as to adjust a distance between the two bodies 23 opposite to each other. That is to say, the first gripping plane P1 and the second gripping plane P2 formed by the individual gripper units 2 are adjustable at least in directions of two axes. In this embodiment, only the gripper unit 2 disposed at the border strip 14 does not include the power member 24, and the remaining three gripper units 2 can all be moved and adjusted by the power members 24 to further grip or release the reticle pod. It should be noted that the present invention is not limited to the examples above. In other examples, all of the four gripper units 2 may include respective power members 24, or only two adjacent gripper units 2 have the respective power member 24. The gripper unit 2 having the power member 24 may be a pneumatic gripper or electrical gripper; that is, the power member 24 pneumatically drives the body 23 or drives the body 23 by means of converting electrical signals to mechanics. The power member 24 may also be a cylinder or a motor that provides power to move the position of the body 23.

In conclusion, the gripping mechanism 100 for the inspection of the reticle inner pod, with the first gripping plane P1 and the second gripping plane P2 formed by the gripper units 2 disposed on the four sides, is capable of stably gripping the reticle inner pod and adapting to upper and lower covers in different sizes and shapes. In an inspection process of the reticle inner pod, the reticle is effectively prevented from falling off as well as damage during transportation or turning of the reticle.

Further, as shown in FIG. 1 to FIG. 2B, in this embodiment, the gripper units 2 further include a plurality of adhesive tapes 25 respectively disposed on positions near the first gripping portion 21 and the second gripping portion 22. The adhesive tape 25 is made of a soft material. By contacting surfaces of the reticle pod with the adhesive tapes 25 when the gripper units 2 grip the reticle pod, the reticle pod is prevented from damage.

Further, as shown in FIG. 1, in this embodiment, the gripper unit 1 further includes a packing element 26. The packing element 26 is connected to the body 23, and is, for example, an element such as an extension spring capable of constantly providing a pushing and packing force in one direction. When the power member 24 encounters an unexpected situation such as power disconnection or pressure disconnection and becomes malfunctional, an effect of the packing element 26 is to provide a pushing force to pack the body 23, preventing the gripper unit 2 from becoming lax and releasing the gripped reticle pod. A hook 261 may be provided on one end of the packing element 26. To manually release the packing force of the packing element 26, packing of the packing element 26 against the body 23 can be relieved by disengaging the hook 261 from the body 23. The packing element 26 is preferably disposed on the gripper unit 2 provided with the power member 24.

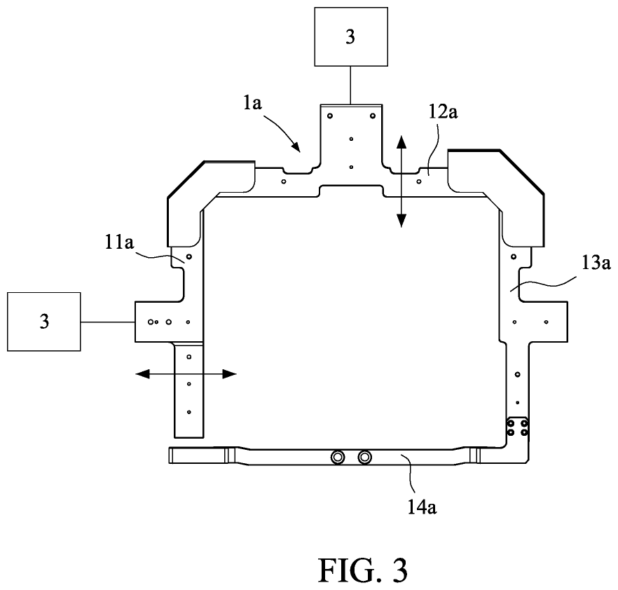

Refer to FIG. 3 (with the gripper units omitted) showing a second embodiment of the present invention. A gripping mechanism for inspection of a reticle inner pod according to the second embodiment of the present invention differs from the first embodiment in that, at least two border strips 11a and 12a of a quadrilateral frame 1a of the second embodiment are in a movable form. With respect to the power member 24 disposed at the gripper unit 2 of the first embodiment, at least two power units 3 are respectively in power connection with the at least two adjacent border strips 11a and 12a in the second embodiment, so as to adjust a distance between two opposite border strips. In other words, in the second embodiment, the distance of the gripper unit 2 disposed on each border strip is changed by adjusting the distance between the border strips. The power units 3 may be a mechanism such as a cylinder or a motor that provides power for reciprocal movements. In other examples, three or more of the border strips may be connected to the power units 3.

The gripper units 2 are similar structures in both of the embodiments and such repeated drawing is not depicted in FIG. 3. Similarly, in this embodiment, the first gripping portion 21 and the second gripping portion 22 are grooves parallel to the border strips, the first gripping portion 21 and the second gripping portion 22 are arranged in parallel in a top-bottom direction (a normal direction of the quadrilateral frame 1), and the second gripping plane P2 is parallel to the first gripping plane P1 and is slightly higher than the first gripping plane P1.

In this embodiment, the gripper unit 2 may similarly include a plurality of adhesive tapes 25 respectively disposed on positions near the first gripping portion 21 and the second gripping portion 22 to prevent the reticle pod from damage during gripping.

While the invention has been described by way of example and in terms of the embodiments, a person skilled in the art should understand that the embodiments are for described the present invention and are not to be construed as limitations to the scope of the present invention. It should be noted that, equivalent modifications, replacements and substitutions made to the embodiments are to be encompassed within the scope of the present invention. Therefore, the scope of protection of the present invention is to be accorded with the broadest interpretation of the appended claims.

What is claimed is:

1. A gripping mechanism for inspection of a reticle inner pod, comprising:
a quadrilateral frame having four border strips; and
a four gripper units respectively disposed at the four border strips, the four gripper units being opposite in pairs, each of the gripper unit having a body, a first gripping portion and a second gripping portion; the first gripping portion and the second gripping portion respectively located on different positions of the body, the respective first gripping portions of the four gripper units forming a first gripping plane, and the respective second gripping portions of the four gripper units forming a second gripping plane;
wherein, at least two adjacent gripper units have a power member, which is in power connection with the bodies so as to adjust a distance between the two bodies.

2. The gripping mechanism for the inspection of the reticle inner pod according to claim 1, wherein the first gripping portion and the second gripping portion are grooves parallel to the border strips.

3. The gripping mechanism for the inspection of the reticle inner pod according to claim 1, wherein the first gripping plane is parallel to the second gripping plane.

4. The gripping mechanism for the inspection of the reticle inner pod according to claim 1, wherein the gripper units further comprise a plurality of adhesive tapes respectively disposed on positions near the first gripping portion and the second gripping portion.

5. The gripping mechanism for the inspection of the reticle inner pod according to claim 1, wherein the gripper units further comprise a packing element, which is connected to the body and packs against the body.

6. A gripping mechanism for inspection of a reticle inner pod, comprising:
a quadrilateral frame having four border strips; and
two power units respectively in power connection with at least two adjacent border strips to adjust a distance between the two border strips; and
a four gripper units respectively disposed at the four border strips, the four gripper units being opposite in pairs, each of the gripper units having a body, a first gripping portion and a second gripping portion; the first gripping portion and the second gripping portion respectively located on different positions of the body, the respective first gripping portions of the four gripper units forming a first gripping plane, and the respective second gripping portions of the four gripper units forming a second gripping plane.

7. The gripping mechanism for the inspection of the reticle inner pod according to claim 6, wherein the first gripping portion and the second gripping portion are grooves parallel to the border strips.

8. The gripping mechanism for the inspection of the reticle inner pod according to claim 6, wherein the first gripping plane is parallel to the second gripping plane.

9. The gripping mechanism for the inspection of the reticle inner pod according to claim 6, wherein the gripper units further comprise a plurality of adhesive tapes respectively disposed on positions near the first gripping portion and the second gripping portion.
